(19) United States
(12) Patent Application Publication
(10) Pub. No.: US 2026/0206143 A1
(43) Pub. Date: Jul. 16, 2026

(54) ELECTRONIC PACKAGE, CARRIER STRUCTURE AND MANUFACTURING METHOD THEREOF

(71) Applicant: SILICONWARE PRECISION INDUSTRIES CO., LTD., Taichung City (TW)

(72) Inventors: Pao-Hung TSENG, Taichung City (TW); Yu-Cheng PAI, Taichung City (TW); Yuan-Ping YEH, Taichung City (TW)

(73) Assignee: SILICONWARE PRECISION INDUSTRIES CO., LTD., Taichung City (TW)

(21) Appl. No.: 19/288,177

(22) Filed: Aug. 1, 2025

(30) Foreign Application Priority Data
Jan. 10, 2025 (TW) 114101168

(51) Int. Cl. H05K 1/18; H01L 21/56; H01L 21/683; H01L 23/00; H01L 23/31; H01L 25/10; H05K 3/34; H05K 3/46

(52) U.S. Cl. CPC H05K 1/185; H05K 1/181; H05K 3/3426; H05K 3/4644; H10P 72/74; H10W 90/00; H10W 74/01; H10W 74/114; H10W 74/15; H10W 90/726; H10W 90/734

(57) ABSTRACT

An electronic package, a carrier structure and a manufacturing method thereof are provided, in which an embedded conductive circuit is formed on a surface of a circuit build-up structure, so that a first electronic component encapsulated in the circuit build-up structure and a second electronic component disposed on the circuit build-up structure can be mounted to opposite sides of the conductive circuit, so as to shorten the signal transmission distance and reduce the package size.

### BACKGROUND

### 1. Technical Field

The present disclosure relates to a semiconductor packaging process, and more particularly, to an electronic package and a carrier structure and a manufacturing method thereof.

### 2. Description of Related Art

In recent years, with the continuous maturity and development of semiconductor process technology, various high-performance electronic products have been continuously introduced. Therefore, the functions of electronic products are developing towards user-friendliness and multi-function. However, electronic products contain various integrated circuit (IC) components with different functions. In the production process of electronic components, integrated circuit packaging (IC packaging) plays a very important role. Integrated circuit packaging types can be roughly divided into two categories: pin in hole (PIH) and surface mount technology (SMT), wherein the pin in hole type includes dual in-line package (DIP) and pin grid array (PGA), and the surface mount technology includes types such as wire bonding (WB) package, tape automatic bonding (TAB) package, flip chip (FC) ball grid array (BGA) package, fan-out package structure, and the like, and wherein each package type has its own particularity and application field.

Please refer to FIG. 1A and FIG. 1B at the same time, which are schematic cross-sectional and partial top views of a conventional multi-chip flip chip ball grid array semiconductor package 1. A first chip 11 and a second chip 12 are electrically connected to a package substrate 10 via a plurality of solder bumps 13, and the first chip 11 and the second chip 12 are disposed side-by-side on the package substrate 10 and are horizontally interconnected for signal transmission by means of a circuit 100 formed on the package substrate 10.

However, in order to cope with the high-speed computing and huge data transmission required by high-performance computing (HPC) and artificial intelligence (AI) technologies, the semiconductor package 1 is unable to meet the current requirements of high-speed transmission and thin and compact end products. The main reason is that the line width/line spacing of the circuit 100 for signal transmission between the first chip 11 and the second chip 12 needs to be less than 5/5 μm, which is beyond the current capability to manufacture the circuit line width/line spacing of 9/12 μm of package substrate, and at the same time, the fine circuit process will face the problem of low yield; in addition, the first chip 11 and the second chip 12 are placed in the same plane horizontally, which requires an increase in the size of the package in the horizontal direction, which is not conducive to the development trend of miniaturization of end products.

Therefore, how to overcome the above-mentioned drawbacks of the prior art has become an urgent issue to be solved.

### SUMMARY

In view of the various deficiencies of the prior art, the present disclosure provides a carrier structure, which comprises: a circuit build-up structure having a first surface and a second surface opposite to the first surface, and including an insulating layer and a circuit layer; a conductive circuit embedded in the first surface of the circuit build-up structure and having a first side and a second side opposite to the first side, wherein the first side of the conductive circuit is exposed from the first surface of the circuit build-up structure; and a first electronic component encapsulated in the insulating layer of the circuit build-up structure and mounted to the second side of the conductive circuit.

The present disclosure further provides an electronic package, which comprises: a carrier structure, including: a circuit build-up structure having a first surface and a second surface opposite to the first surface, and including an insulating layer and a circuit layer; a conductive circuit embedded in the first surface of the circuit build-up structure and having a first side and a second side opposite to the first side, wherein the first side of the conductive circuit is exposed from the first surface of the circuit build-up structure; and a first electronic component encapsulated in the insulating layer of the circuit build-up structure and mounted to the second side of the conductive circuit; and a second electronic component disposed on the first surface of the circuit build-up structure and mounted to the first side of the conductive circuit.

In the aforementioned carrier structure and electronic package, the conductive circuit includes a plurality of electrical connection pads, the first electronic component is mounted to a side of the plurality of electrical connection pads via a plurality of first conductive bumps, and the second electronic component is mounted to the other side of the plurality of electrical connection pads via a plurality of second conductive bumps.

In the aforementioned carrier structure and electronic package, a line width/line spacing of the conductive circuit is smaller than a line width/line spacing of the circuit layer.

In the aforementioned carrier structure and electronic package, the present disclosure further comprises protective layers formed on the circuit build-up structure, wherein openings are formed on the protective layers to expose the conductive circuit and the circuit layer.

In the aforementioned electronic package, the present disclosure further comprises an encapsulation layer formed on the first surface of the circuit build-up structure and encapsulating the second electronic component.

In the aforementioned electronic package, the present disclosure further comprises a plurality of conductive components disposed on the second surface of the circuit build-up structure.

The present disclosure also provides a method of manufacturing a carrier structure, the method comprises: providing a carrier; forming a conductive circuit on the carrier; disposing a first electronic component on the conductive circuit; forming a circuit build-up structure on the conductive circuit and the first electronic component, wherein the circuit build-up structure has a first surface and a second surface opposite to the first surface, and includes an insulating layer and a circuit layer, wherein the conductive circuit is embedded in the first surface of the circuit build-up structure, and the first electronic component is encapsulated in the insulating layer of the circuit build-up structure; and removing the carrier.

The present disclosure further provides a method of manufacturing an electronic package, the method comprises: providing a carrier; forming a conductive circuit on the carrier; disposing a first electronic component on the conductive circuit; forming a circuit build-up structure on the conductive circuit and the first electronic component, wherein the circuit build-up structure has a first surface and a second surface opposite to the first surface, and includes an insulating layer and a circuit layer, wherein the conductive circuit is embedded in the first surface of the circuit build-up structure, and the first electronic component is encapsulated in the insulating layer of the circuit build-up structure; removing the carrier to expose the conductive circuit from the first surface of the circuit build-up structure; and disposing a second electronic component on the conductive circuit exposed from the first surface of the circuit build-up structure.

In the aforementioned method, the carrier includes a board body, each of two surfaces of the board body is provided with a release layer, and a metal layer is formed on each of the release layers.

As can be seen from the above, in the electronic package, the carrier structure and the manufacturing method thereof of the present disclosure, an embedded conductive circuit is formed on the surface of the circuit build-up structure. Accordingly, the present disclosure not only has the capability of fine circuit, but also enables the first electronic component encapsulated in the circuit build-up structure and the second electronic component disposed on the circuit build-up structure to be mounted to the opposite sides of the conductive circuit for vertical signal transmission, thereby shortening the signal transmission distance and reducing the package area and package height.

### BRIEF DESCRIPTION OF THE DRAWINGS

FIG. 1A is a schematic cross-sectional view of a conventional semiconductor package.

FIG. 1B is a partial top view of the conventional semiconductor package.

FIG. 2A to FIG. 2I are schematic cross-sectional views illustrating a carrier structure, an electronic package and a manufacturing method thereof according to the present disclosure.

FIG. 3 is a partial top view of the electronic package according to the present disclosure.

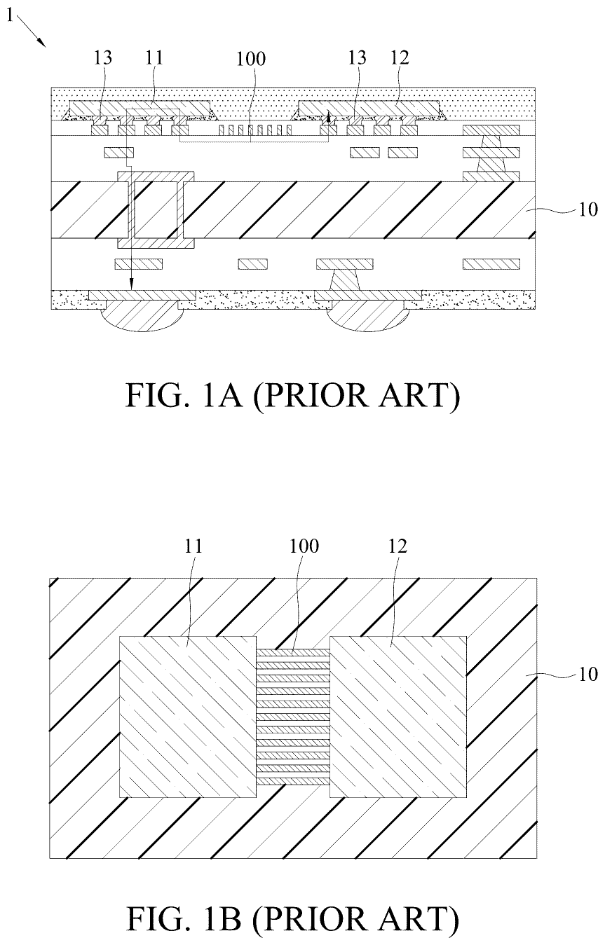

### DETAILED DESCRIPTION

The following describes the embodiments of the present disclosure with examples. Those skilled in the art can easily understand other advantages and effects of the present disclosure from the contents disclosed in this specification.

It should be understood that, the structures, ratios, sizes, and the like in the accompanying figures are used for illustrative purposes to facilitate the perusal and comprehension of the contents disclosed in the present specification by one skilled in the art, rather than to limit the conditions for practicing the present disclosure. Any modification of the structures, alteration of the ratio relationships, or adjustment of the sizes without affecting the possible effects and achievable proposes should still be deemed as falling within the scope defined by the technical contents disclosed in the present specification. Meanwhile, terms such as “on,” “first,” “second,” “a,” “one,” and the like are merely used for clear explanation rather than limiting the practicable scope of the present disclosure, and thus, alterations or adjustments of the relative relationships thereof without essentially altering the technical contents should still be considered in the practicable scope of the present disclosure.

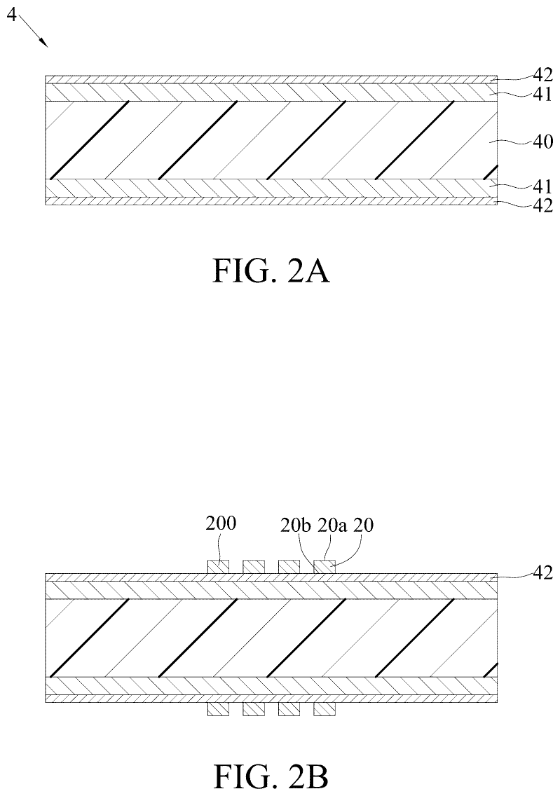

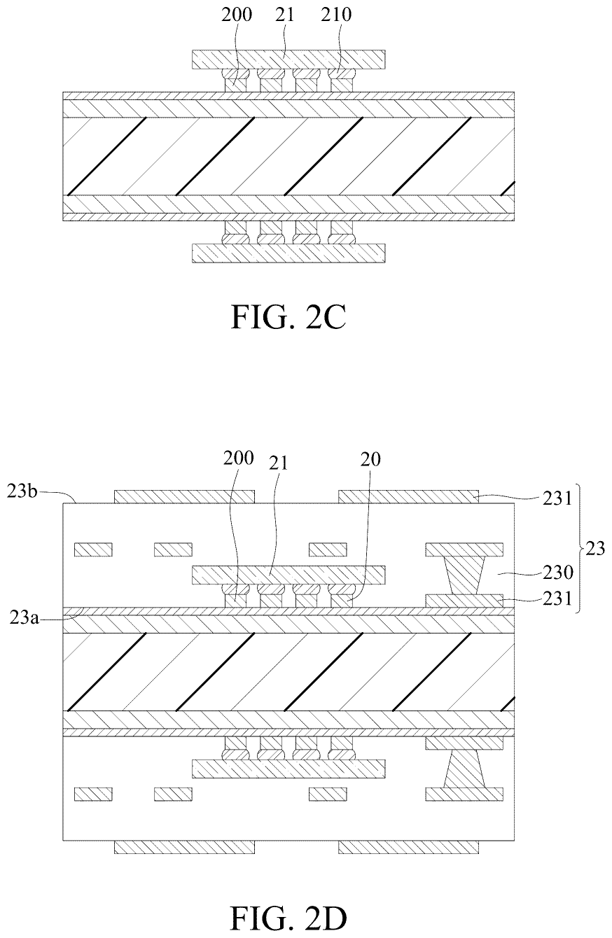

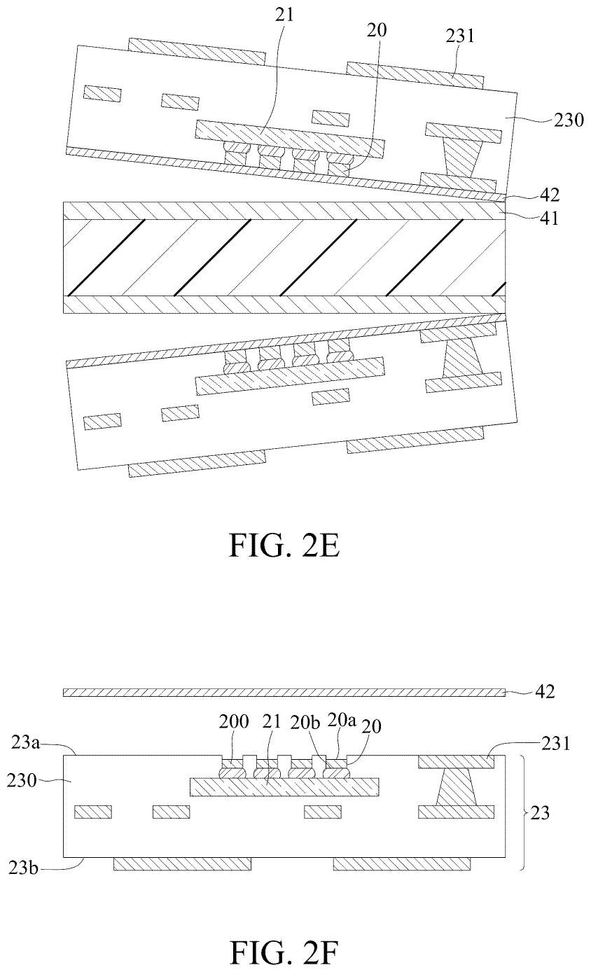

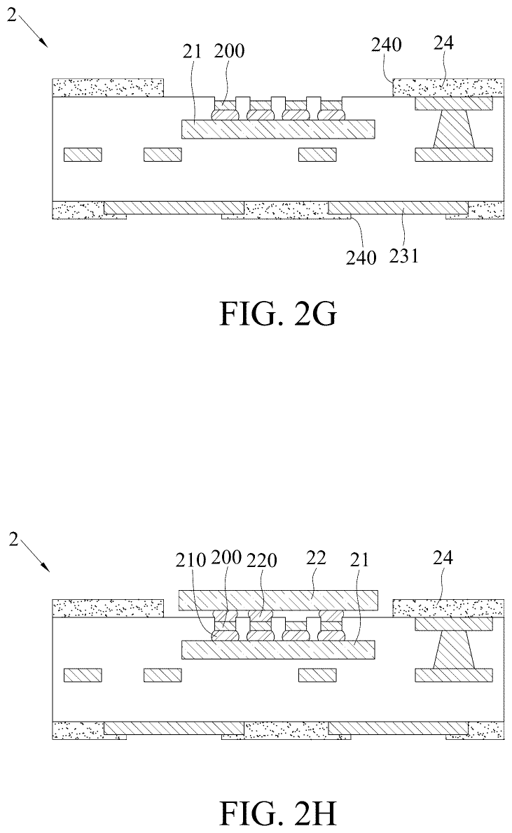

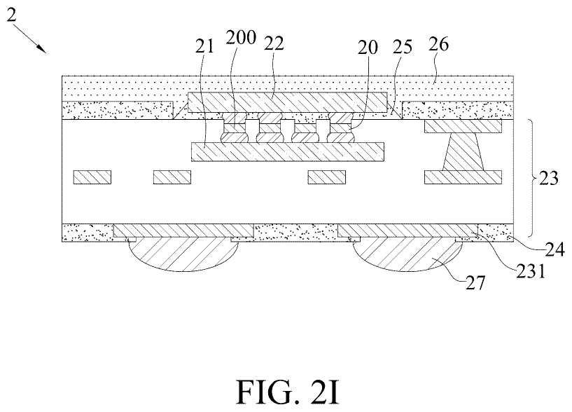

Please refer to FIG. 2A to FIG. 2I, which are schematic cross-sectional views illustrating a manufacturing method of an electronic package 3 and a carrier structure 2 thereof according to the present disclosure.

As shown in FIG. 2A, a carrier 4 is provided. The carrier 4 is a temporary carrier, which can be a board (such as a copper foil substrate) with metal surfaces on two opposite sides. The carrier 4 mainly includes a board body 40, release layers 41 and metal layers 42. That is, each of the two surfaces of the board body 40 is provided with the release layer 41, and the metal layer 42 such as a copper layer is formed on each of the release layers 41.

As shown in FIG. 2B, a patterning process is performed to form a conductive circuit 20 including a plurality of electrical connection pads 200 on the metal layer 42. In one embodiment, the conductive circuit 20 is made of copper.

In one embodiment, the metal layer 42 is used as a seed layer to electroplate copper material to form the conductive circuit 20. Furthermore, the conductive circuit 20 is made with a fine line width/line spacing specification and has a line width/line spacing of such as 8 microns/10 microns.

As shown in FIG. 2C, a first electronic component 21 is disposed on the conductive circuit 20 so that the first electronic component 21 is mounted to and electrically connected to the plurality of electrical connection pads 200.

In one embodiment, the first electronic component 21 is mounted to the plurality of electrical connection pads 200 via a plurality of first conductive bumps 210.

As shown in FIG. 2D, a circuit build-up structure 23 is formed on the conductive circuit 20 and the first electronic component 21. The circuit build-up structure 23 includes a plurality of insulating layers 230 and a plurality of circuit layers 231 formed on the plurality of insulating layers 230 to form a coreless circuit build-up structure, and the conductive circuit 20 and the first electronic component 21 are embedded in the circuit build-up structure 23.

In one embodiment, the insulating layer 230 covers the first electronic component 21 by, for example, lamination, and the conductive circuit 20 is embedded in the insulating layer 230 to form an embedded circuit. The insulating layer 230 is made of dielectric material such as prepreg (PP), polybenzoxazole (PBO), polyimide (PI), or others. The circuit layer 231 is formed by a build-up process by electroplating metal (such as copper) or by other methods. Furthermore, the line width/line spacing of the conductive circuit 20 is smaller than the line width/line spacing of the circuit layer 231. For example, the line width/line spacing of the circuit layer 231 is 9 microns/12 microns.

As shown in FIG. 2E, the release layer 41 is separated from the metal layer 42 by peeling or other methods, and the metal layer 42 remains on the insulating layer 230 of the circuit build-up structure 23 and the conductive circuit 20.

As shown in FIG. 2F, the metal layer 42 is removed to expose the surface of the insulating layer 230 and the conductive circuit 20. In one embodiment, the metal layer 42 can be removed by etching, and at the same time, a portion of the material of the conductive circuit 20 and a portion of the material of the circuit layer 231 are micro-etched to avoid short circuits caused by connection between adjacent circuits.

As shown in FIG. 2G, in one embodiment, a protective layer 24 made of such as solder resist material can be formed on the conductive circuit 20 and on each of the opposite sides of the circuit build-up structure 23 as required, and openings 240 are formed on the protective layers 24 to expose the conductive circuit 20 (the electrical connection pads 200) and the circuit layer 231 of the circuit build-up structure 23, so as to obtain the carrier structure 2 of the present disclosure.

As shown in FIG. 2H, next, a second electronic component 22 is placed on the carrier structure 2 at a position corresponding to the first electronic component 21.

In one embodiment, the second electronic component 22 is mounted to the plurality of electrical connection pads 200 via a plurality of second conductive bumps 220, so that the first electronic component 21 is connected to a side of the plurality of electrical connection pads 200 while the second electronic component 22 is connected to the other side of the plurality of electrical connection pads 200. Accordingly, the first electronic component 21 and the second electronic component 22 can be directly and quickly electrically connected via the first conductive bumps 210, the plurality of electrical connection pads 200 and the second conductive bumps 220, thereby avoiding the problem of having to make fine circuits between two chips when multiple chips are placed horizontally on the same plane, as well as the problem of increasing the size of the package in the horizontal direction.

As shown in FIG. 2I, an underfill 25 is formed between the second electronic component 22 and the carrier structure 2. An encapsulation layer 26 can be formed on the carrier structure 2 to encapsulate the second electronic component 22 as required, and conductive components 27 such as solder balls are formed on portions of the circuit layer 231 that are exposed from the protective layer 24 to obtain the electronic package 3 of the present disclosure.

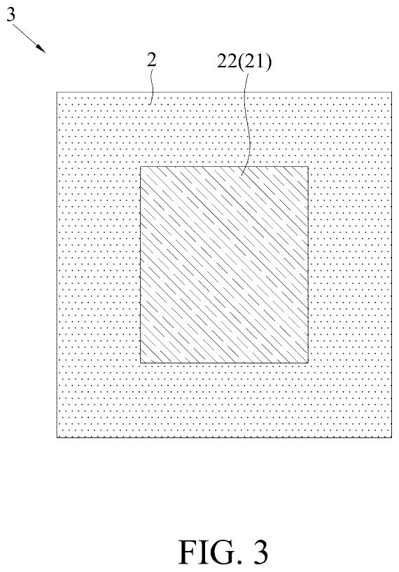

Please also refer to FIG. 3, which is a partial top view of the electronic package 3, wherein the number of the electrical contacts (the first conductive bumps 210) of the first electronic component 21 and the number of the electrical contacts (the second conductive bumps 220) of the second electronic component 22 may be the same or different. If the numbers of the electrical contacts of the first electronic component 21 and the second electronic component 22 are different, the first electronic component 21 and the second electronic component 22 can completely overlap; if the numbers of the electrical contacts of the first electronic component 21 and the second electronic component 22 are the same, the first electronic component 21 and the second electronic component 22 do not completely overlap, because some electrical contacts need to be routed out, so that the first electronic component 21 and the second electronic component 22 can be electrically connected to an external area.

By means of the aforementioned manufacturing method, the present disclosure further discloses a carrier structure 2 and an electronic package 3.

The carrier structure 2 includes a circuit build-up structure 23, a conductive circuit 20 and a first electronic component 21.

The circuit build-up structure 23 has a first surface 23a and a second surface 23b opposite to the first surface 23a, and includes a plurality of insulating layers 230 and a plurality of circuit layers 231.

The conductive circuit 20 is embedded in the first surface 23a of the circuit build-up structure 23 and has a first side 20a and a second side 20b opposite to the first side 20a, so that the first side 20a of the conductive circuit 20 is exposed from the first surface 23a of the circuit build-up structure 23.

The first electronic component 21 is encapsulated in the insulating layer 230 of the circuit build-up structure 23 and is mounted to the second side 20b of the conductive circuit 20.

The electronic package 3 includes the carrier structure 2 and a second electronic component 22 disposed on the carrier structure 2.

The second electronic component 22 is disposed on the first surface 23a of the circuit build-up structure 23 and is mounted to the first side 20a of the conductive circuit 20.

The conductive circuit 20 has a plurality of electrical connection pads 200, so that the first electronic component 21 is mounted to a side of the plurality of electrical connection pads 200 via a plurality of first conductive bumps 210, and the second electronic component 22 is mounted to the other side of the plurality of electrical connection pads 200 via a plurality of second conductive bumps 220.

The electronic package 3 includes an encapsulation layer 26 and a plurality of conductive components 27. The encapsulation layer 26 is formed on the first surface 23a of the circuit build-up structure 23 to encapsulate the second electronic component 22. The plurality of conductive components 27 are disposed on the second surface 23b of the circuit build-up structure 23 to electrically connect to an external device.

To sum up, in the electronic package, the carrier structure and the manufacturing method thereof of the present disclosure, an embedded conductive circuit is formed on the surface of the circuit build-up structure. Accordingly, the present disclosure not only has the capability of fine circuit, but also enables the first electronic component encapsulated in the circuit build-up structure and the second electronic component disposed on the circuit build-up structure to be mounted to the opposite sides of the conductive circuit for vertical signal transmission, thereby shortening the signal transmission distance and reducing the package area and package height. In addition, the present disclosure can be manufactured using existing semiconductor packaging processes without the need to develop special processes or purchase special equipment, thereby reducing product production costs.

The foregoing embodiments are provided for the purpose of illustrating the principles and effects of the present disclosure, rather than limiting the present disclosure. Anyone skilled in the art can modify and alter the above embodiments without departing from the spirit and scope of the present disclosure. Therefore, the scope of protection with regard to the present disclosure should be as defined in the accompanying claims listed below.

What is claimed is:

1. A carrier structure, comprising:
a circuit build-up structure having a first surface and a second surface opposite to the first surface, and including an insulating layer and a circuit layer;
a conductive circuit embedded in the first surface of the circuit build-up structure and having a first side and a second side opposite to the first side, wherein the first side of the conductive circuit is exposed from the first surface of the circuit build-up structure; and
a first electronic component encapsulated in the insulating layer of the circuit build-up structure and mounted to the second side of the conductive circuit.

2. The carrier structure of claim 1, wherein the conductive circuit includes a plurality of electrical connection pads, and the first electronic component is mounted to the plurality of electrical connection pads via a plurality of first conductive bumps.

3. The carrier structure of claim 1, further comprising protective layers formed on the circuit build-up structure, wherein openings are formed on the protective layers to expose the conductive circuit and the circuit layer.

4. The carrier structure of claim 1, wherein a line width/line spacing of the conductive circuit is smaller than a line width/line spacing of the circuit layer.

5. An electronic package, comprising:
a carrier structure, including:
a circuit build-up structure having a first surface and a second surface opposite to the first surface, and including an insulating layer and a circuit layer;
a conductive circuit embedded in the first surface of the circuit build-up structure and having a first side and a second side opposite to the first side, wherein the first side of the conductive circuit is exposed from the first surface of the circuit build-up structure; and
a first electronic component encapsulated in the insulating layer of the circuit build-up structure and mounted to the second side of the conductive circuit; and
a second electronic component disposed on the first surface of the circuit build-up structure and mounted to the first side of the conductive circuit.

6. The electronic package of claim 5, wherein the conductive circuit includes a plurality of electrical connection pads, the first electronic component is mounted to a side of the plurality of electrical connection pads via a plurality of first conductive bumps, and the second electronic component is mounted to the other side of the plurality of electrical connection pads via a plurality of second conductive bumps.

7. The electronic package of claim 5, wherein a line width/line spacing of the conductive circuit is smaller than a line width/line spacing of the circuit layer.

8. The electronic package of claim 5, further comprising protective layers formed on the circuit build-up structure, wherein openings are formed on the protective layers to expose the conductive circuit and the circuit layer.

9. The electronic package of claim 5, further comprising an encapsulation layer formed on the first surface of the circuit build-up structure and encapsulating the second electronic component.

10. The electronic package of claim 5, further comprising a plurality of conductive components disposed on the second surface of the circuit build-up structure.

11. A method of manufacturing a carrier structure, comprising:
providing a carrier;
forming a conductive circuit on the carrier;
disposing a first electronic component on the conductive circuit;
forming a circuit build-up structure on the conductive circuit and the first electronic component, wherein the circuit build-up structure has a first surface and a second surface opposite to the first surface, and includes an insulating layer and a circuit layer, wherein the conductive circuit is embedded in the first surface of the circuit build-up structure, and the first electronic component is encapsulated in the insulating layer of the circuit build-up structure; and
removing the carrier.

12. The method of claim 11, wherein the carrier includes a board body, each of two surfaces of the board body is provided with a release layer, and a metal layer is formed on each of the release layers.

13. The method of claim 11, wherein the conductive circuit includes a plurality of electrical connection pads, and the first electronic component is mounted to the plurality of electrical connection pads via a plurality of first conductive bumps.

14. The method of claim 11, further comprising forming protective layers on the circuit build-up structure, and forming openings on the protective layers to expose the conductive circuit and the circuit layer.

15. The method of claim 11, wherein a line width/line spacing of the conductive circuit is smaller than a line width/line spacing of the circuit layer.

16. A method of manufacturing an electronic package, comprising:
providing a carrier;
forming a conductive circuit on the carrier;
disposing a first electronic component on the conductive circuit;
forming a circuit build-up structure on the conductive circuit and the first electronic component, wherein the circuit build-up structure has a first surface and a second surface opposite to the first surface, and includes an insulating layer and a circuit layer, wherein the conductive circuit is embedded in the first surface of the circuit build-up structure, and the first electronic component is encapsulated in the insulating layer of the circuit build-up structure;
removing the carrier to expose the conductive circuit from the first surface of the circuit build-up structure; and
disposing a second electronic component on the conductive circuit exposed from the first surface of the circuit build-up structure.

17. The method of claim 16, wherein the carrier includes a board body, each of two surfaces of the board body is provided with a release layer, and a metal layer is formed on each of the release layers.

18. The method of claim 16, wherein the conductive circuit includes a plurality of electrical connection pads, the first electronic component is mounted to a side of the plurality of electrical connection pads via a plurality of first conductive bumps, and the second electronic component is mounted to the other side of the plurality of electrical connection pads via a plurality of second conductive bumps.

19. The method of claim 16, wherein a line width/line spacing of the conductive circuit is smaller than a line width/line spacing of the circuit layer.

20. The method of claim 16, further comprising forming protective layers on the circuit build-up structure, and forming openings on the protective layers to expose the conductive circuit and the circuit layer.

21. The method of claim 16, further comprising forming an encapsulation layer on the first surface of the circuit build-up structure to encapsulate the second electronic component.

22. The method of claim 16, further comprising disposing a plurality of conductive components on the second surface of the circuit build-up structure.
